(19) United States
(12) Patent Application Publication
(10) Pub. No.: US 2009/0183558 A1
(43) Pub. Date: Jul. 23, 2009

(54) Cam/crank sensor that allows for multiple orientations of a plastic over-molded bracket relative to a molded sensor terminal assembly

(76) Inventors: Xin Houjie, Chihuahua (MX); Samuel Roland Palfenier, El Paso, TX (US); Luis A. Flores-Mena, Chihuahua (MX)

Correspondence Address: DELPHI TECHNOLOGIES, INC., M/C 480-410-202, PO BOX 5052, TROY, MI, 48007, US

(21) Appl. No.: 12/009,651

(22) Filed: Jan. 22, 2008

(51) Int. Cl. G01M 15/06; G01B 21/22; G01R 3/00

(52) U.S. Cl. 73/114.26; 73/865.9; 29/595

(57) ABSTRACT

A vehicle camshaft/crankshaft sensor has a plastic terminal assembly defining a connector and a plastic housing and bracket assembly engaged with the terminal assembly and defining a plastic bracket. Various structures are disclosed for establishing one of plural discrete orientations between the bracket and the connector.

### I. FIELD OF THE INVENTION

The present invention relates generally to vehicle cam/crank sensors that allow for multiple orientations of a plastic over-molded bracket relative to a molded sensor terminal assembly.

### II. BACKGROUND OF THE INVENTION

In many of today's vehicles, sensors that sense the position of a camshaft or crankshaft by, e.g., sensing the position of a target wheel that rotates with the shaft are used for generating signals representing the angular position of the cam or crankshaft. These position signals can be used in distributorless ignition systems that have selectively energized ignition coils that fire the spark plugs as appropriate for the angular position of the shaft. Moreover, the crankshaft angular position signals can be used for combustion control and diagnostic functions, although the precise functions for which the sensors are used are not necessarily limiting to the invention.

As understood herein, owing to different vehicle configurations, the bracket that is used to mount the sensor may have to assume one of several different orientations relative to the terminal assembly of the sensor. When the bracket is metal, this entails crimping the bracket to the sensor terminal assembly in the orientation desired for the vehicle for which the sensor is intended, but the present invention recognizes the desirability of avoiding both the added cost of using a metal bracket and the added assembly cost of crimping. On the other hand, the present invention recognizes that a plastic bracket can be overmolded onto the terminal assembly but a separate mold is then required for each desired bracket-to-terminal assembly orientation.

### SUMMARY OF THE INVENTION

A sensor includes a sensor element configured for generating a signal representative of an angular position of a rotational shaft. The sensor has a terminal assembly and a housing and bracket assembly engaged with the terminal assembly in a desired one of plural predetermined discrete orientations and in no other orientations. The sensor element is supported by the terminal assembly and/or housing and bracket assembly. A connector is formed on the terminal assembly and holds one or more electrical connectors. The connector is configured for engaging a connector of a vehicle to provide a pathway for communication between the sensor element and a vehicle receiver, such as an engine control module. Also, a bracket is formed on the housing and bracket assembly and is configured for mounting the sensor to a vehicle. In accordance with present principles, plural discrete orientation-establishing terminal orientation elements are on the terminal assembly, and likewise plural discrete orientation-establishing bracket orientation elements are on the housing and bracket assembly. The bracket orientation elements are configured for engaging respective terminal orientation elements to establish the desired one of plural predetermined discrete orientations.

If desired, the assemblies may be heat staked together in the desired one of the orientations. The terminal orientation elements can be straight sides of a multi-sided (e.g., hexagonal) orientation flange of the terminal assembly, and similarly the bracket orientation elements can be straight sides of an orientation surface of the holder assembly. Or, the terminal orientation elements can be plural discrete radial or axial protrusions formed around an open end of the terminal assembly and the holder elements can be plural discrete notches formed around an end of the holder assembly.

In another aspect, a method of making a cam/crank shaft sensor includes supporting a sensor element in a terminal assembly and/or a housing and bracket assembly, and rotating one of the assemblies relative to the other assembly until a desired one of predetermined orientations between the assemblies is established. The method also includes preventing translationally moving one assembly into the other assembly in any orientation other than one of the predetermined orientations. One assembly is translationally moved into the other assembly and then the assemblies are fastened together in the desired orientation.

In yet another aspect, a vehicle camshaft or crankshaft angular position sensor includes a plastic terminal assembly defining a connector and a plastic housing and bracket assembly engaged with the terminal assembly and defining a plastic bracket. Means are provided on the assemblies for establishing one of plural discrete orientations between the bracket and the connector.

The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is an exploded perspective view of an embodiment of the present sensor;

FIG. 2 is a perspective view that shows the sensor of FIG. 1 with the bracket heat-staked in a first orientation relative to the terminal assembly;

FIG. 3 is a perspective view that shows the sensor of FIG. 1 with the bracket heat-staked in a second orientation relative to the terminal assembly;

FIG. 4 is a perspective view of an alternate embodiment of the sensor;

FIG. 5 is an exploded perspective view of another alternate embodiment of the sensor; and

FIG. 6 is an exploded perspective view of yet another alternate embodiment of the sensor.

### DETAILED DESCRIPTION OF THE PREFERRED EMBODIMENT

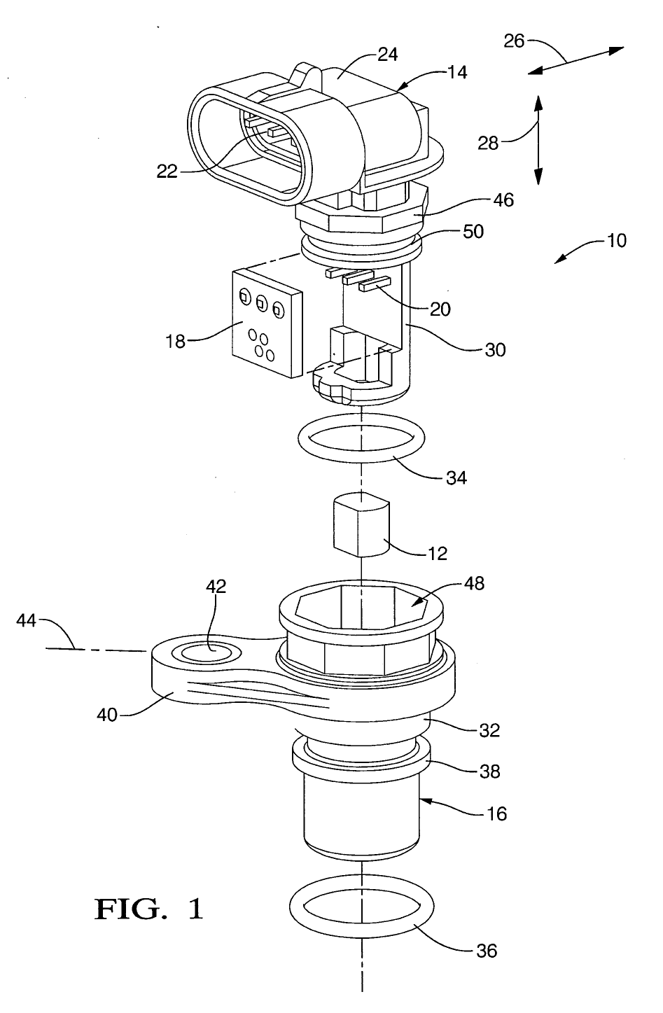

Referring initially to FIG. 1, a sensor is shown, generally designated 10, that may use the Hall effect or magnetoresistive (MR) effect device to sense the speed and/or position of a shaft such as an engine crankshaft or camshaft by, e.g., sensing the position of a target wheel that rotates with the shaft. When the Hall effect is used, a Hall device 12 may be provided in a sensor body defined by two hollow plastic parts, namely, a terminal assembly 14 and a housing and bracket assembly 16, it being understood that present principles are not necessarily limited to Hall effect sensors unless otherwise claimed. The Hall device 12 may be electrically connected to a circuit board 18 that is held in the terminal assembly 14 and that is electrically connected to internal electrical connectors 20 over which the terminal assembly is molded.

In turn, the internal electrical connectors 20 are electrically connected to main electrical connectors 22 that are disposed in a hollow, open-ended connector portion 24 of the terminal assembly 14. It will readily be appreciated that a complementarily-shaped connector, e.g., a male connector (not shown) of a vehicle may be inserted into the connector portion 24 to electrically engage the main connectors 22 to provide a means for conveying the signal from the Hall device 12 to, e.g., an engine control module (ECM) or other control module. The connectors 22 of the connector portion 24 define a connector axis 26 that, in the embodiment shown, may be perpendicular to the axis 28 defined by the portion 30 of the terminal assembly 14 that holds the internal connectors 20.

It will be appreciated looking at FIG. 1 that the portion 30 of the terminal assembly 14 that holds the circuit board 18 and internal connectors 20 is sized to be received within an enclosure portion 32 of the housing and bracket assembly 16. An internal o-ring 34 may be provided between the portions 30, 32 as shown to seal the circuit board 18 and other internal components from external contaminants, and an external o-ring 36 may be provided around the outside of the enclosure portion 32 to abut a flange 38 made integrally therewith to also provide a seal.

The housing and bracket assembly 16 is formed with a bracket mount 40 that extends radially away from the holder portion 32 as shown. The mount 40 can be formed with a mount opening 42 with which a fastener or other mounting component can be engaged to hold the sensor 10 onto a vehicle. The mount 40 extends away from the holder portion 32 along a mount axis 44.

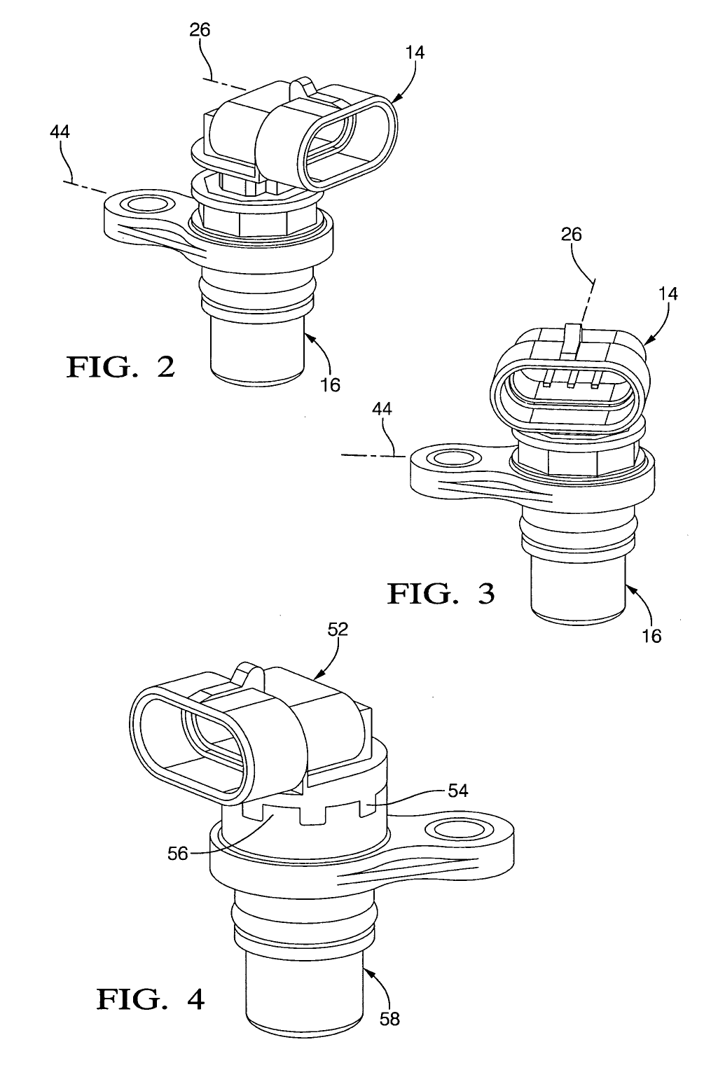

Referring briefly to FIGS. 2 and 3, the orientation of the housing and bracket assembly 16 with respect to the terminal assembly 14 is established by the orientation between these two parts when the portion 30 of the terminal assembly 14 that holds the internal connectors 20 is pressed into the holder portion 32. For example, in FIG. 2 the mount axis 44 is parallel to the connector axis 26 as shown (and in fact the mount 40 is oriented 180 degrees opposite the open end of the connector portion 24 as shown), whereas in FIG. 3 the mount axis 44 is perpendicular to the connector axis 26. It is the purpose of the present invention to allow facile engagement of the two parts in a desired one of multiple predetermined orientations while preventing establishing an orientation other than one of the predetermined orientations.

One way to achieve this function is shown in FIG. 1. An orientation flange 46 is formed integrally with the portion 30 of the terminal assembly 14 that holds the internal connectors 20, and the orientation flange 46 engages a complementarily-shaped orientation surface 48 of the holder portion 32. In the embodiment shown, the establishment of one of eight predetermined orientations is desired, with the orientation flange 46 and orientation surface 48 consequently being octagonal. Once the portion 30 of the terminal assembly 14 that holds the internal connectors 20 has been advanced into holder portion 32 in the desired orientation, the parts can be heat-staked together. To this end, a heat-stake groove 50 can be formed in the portion 30 of the terminal assembly 14 if desired. The holder assembly 16 may include a metal bushing in the mount opening 42, and may be filled with silicon potting to protect the sensor components held therein.

In general, the orientation structure of the present invention includes complementarily-shaped structures on the terminal assembly 14 and holder assembly 16 that each include at least one and preferably plural discrete surfaces that in turn establish predetermined orientation keys, so that an infinite number of orientations is not provided but only a predetermined number and direction of orientations is provided.

FIGS. 4-6 provide further illustrations of this principle. In FIG. 4, a terminal assembly 52 is formed with plural discrete axial protrusions 54 around an open end of the terminal assembly, with the protrusions 54 pressed down into respective notches 56 formed around an upper end of a housing and bracket assembly 58. It will readily be appreciated that the orientation of the terminal assembly 52 with respect to the housing and bracket assembly 58 is established and then the protrusions 54 engaged with the notches 56 to hold the parts in the desired orientation, followed by heat staking, or ultrasonic welding, or solvent bonding, or other appropriate fastening modality.

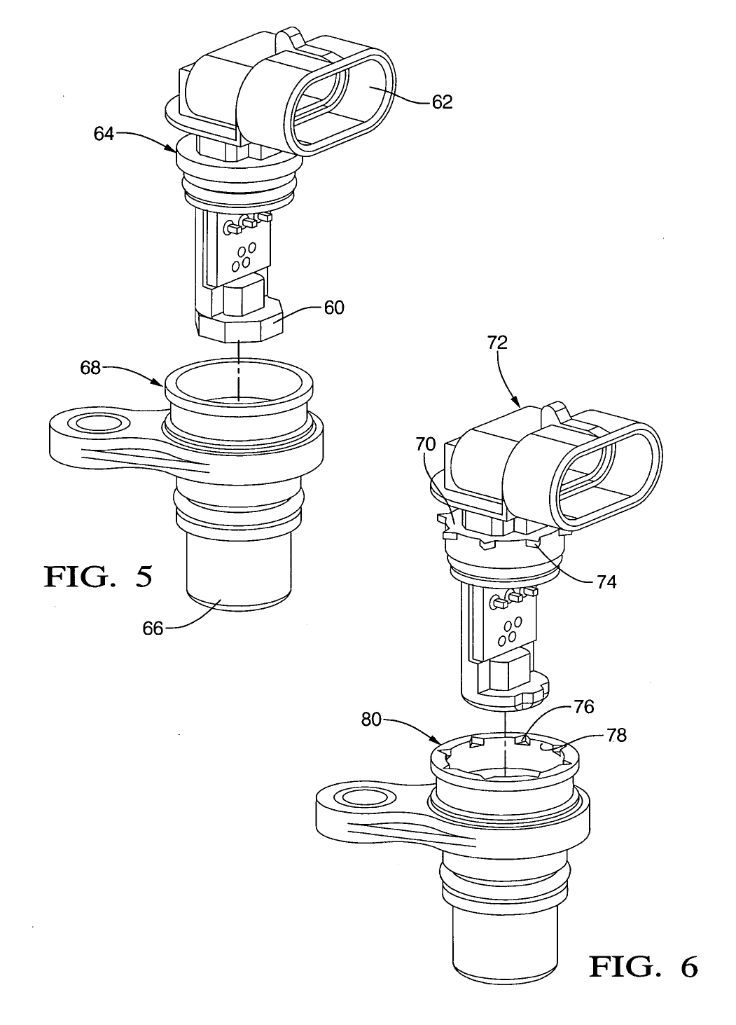

FIG. 5 shows that a bottom 60 that is opposite a connector 62 of a terminal assembly 64 can have a non-round, e.g., hexagonal shape if eight possible orientations are desired, or a square shape if four orientations are desired, or a triangular shape if only three orientations are desired, etc. for fitting within a complementarily-shaped inside orientation surface formed at the bottom 66 of a housing and bracket assembly 68. Yet again, as shown in FIG. 6, in lieu of discrete multiple contiguous sides, the orientation structure can have discrete spike-like protrusions. More particularly, an orientation flange 70 of a terminal assembly 72 can be formed with plural spike-like radial protrusions 74 that engage complementary radial notches 76 of an inside surface 78 of a housing and bracket assembly 80.

While the particular CAM/CRANK SENSOR THAT ALLOWS FOR MULTIPLE ORIENTATIONS OF A PLASTIC OVER-MOLDED BRACKET RELATIVE TO A MOLDED TERMINAL ASSEMBLY is herein shown and described in detail, it is to be understood that the subject matter which is encompassed by the present invention is limited only by the claims.

What is claimed is:

1. A sensor, comprising:
at least one sensor element configured for generating a signal representative of an angular position of a rotatable shaft;
a terminal assembly;
a housing and bracket assembly engaged with the terminal assembly in a desired one of plural predetermined discrete orientations and in no other orientations, the sensor element being supported by the terminal assembly and/or housing and bracket assembly;
a connector formed on the terminal assembly and holding at least one electrical connector, the connector being configured for engaging a connector of a vehicle to provide a pathway for communication between the sensor element and a vehicle receiver;
a bracket formed on the housing and bracket assembly and configured for mounting the sensor to a vehicle;
plural discrete orientation-establishing terminal orientation elements on the terminal assembly; and
plural discrete orientation-establishing bracket orientation elements on the housing and bracket assembly and being configured for engaging respective terminal orientation elements to establish the desired one of plural predetermined discrete orientations.

2. The sensor of claim 1, wherein the assemblies are heat staked together in the desired one of the orientations.

3. The sensor of claim 1, wherein the terminal orientation elements are straight sides of a multi-sided orientation flange of the terminal assembly and the bracket orientation elements are straight sides of an orientation surface of the housing and bracket assembly.

4. The sensor of claim 3, wherein the orientation flange and orientation surface each have eight respective sides.

5. The sensor of claim 1, wherein the terminal orientation elements are plural discrete protrusions formed around an open end of the terminal assembly and the holder elements are plural discrete notches formed around an end of the housing and bracket assembly.

6. The sensor of claim 5, wherein the protrusions are oriented axially on the terminal assembly.

7. The sensor of claim 5, wherein the protrusions are oriented radially on the terminal assembly.

8. A method of making a shaft sensor, comprising:
supporting a sensor element in a terminal assembly and/or a housing and bracket assembly;
rotating one of the assemblies relative to the other assembly until a desired one of predetermined orientations between the assemblies is established;
preventing translationally moving one assembly into the other assembly in any orientation other than one of the predetermined orientations;
translationally moving one assembly into the other assembly; and
fastening the assemblies together in the desired orientation.

9. The method of claim 8, wherein the assemblies are fastened together in the desired orientation using heat staking.

10. The method of claim 8, wherein the act of preventing is established by providing plural discrete orientation-establishing terminal orientation elements on the terminal assembly and plural discrete orientation-establishing bracket orientation elements on the housing and bracket assembly, the bracket orientation elements being configured for engaging respective terminal orientation elements.

11. The method of claim 10, wherein the terminal orientation elements are straight sides of a multi-sided orientation flange of the terminal assembly and the bracket orientation elements are straight sides of an orientation surface of the housing and bracket assembly.

12. The method of claim 10, wherein the terminal orientation elements are plural discrete protrusions formed around an open end of the terminal assembly and the holder elements are plural discrete notches formed around an end of the housing and bracket assembly.

13. The method of claim 12, wherein the protrusions are oriented axially on the terminal assembly.

14. The method of claim 12, wherein the protrusions are oriented radially on the terminal assembly.

15. A vehicle camshaft or crankshaft angular position sensor, comprising:
a plastic terminal assembly defining a connector;
a plastic housing and bracket assembly engaged with the terminal assembly and defining a plastic bracket; and
means formed on the assemblies for establishing one of plural discrete orientations between the bracket and the connector.

16. The sensor of claim 15, wherein the means for establishing includes:
plural discrete orientation-establishing terminal orientation elements on the terminal assembly; and
plural discrete orientation-establishing bracket orientation elements on the housing and bracket assembly and configured for engaging respective terminal orientation elements.

17. The sensor of claim 16, wherein the terminal orientation elements are straight sides of a multi-sided orientation flange of the terminal assembly and the bracket orientation elements are straight sides of an orientation surface of the housing and bracket assembly.

18. The sensor of claim 16, wherein the terminal orientation elements are plural discrete protrusions formed around an open end of the terminal assembly and the holder elements are plural discrete notches formed around an end of the housing and bracket assembly.

19. The sensor of claim 18, wherein the protrusions are oriented axially on the terminal assembly.

20. The sensor of claim 18, wherein the protrusions are oriented radially on the terminal assembly.
